(19) United States
(12) Patent Application Publication
(10) Pub. No.: US 2022/0317555 A1
(43) Pub. Date: Oct. 6, 2022

(54) HALFTONE MASK, MANUFACTURING METHOD OF DISPLAY PANEL, AND ULTRAVIOLET MASK

(71) Applicant: WUHAN CHINA STAR OPTOELECTRONICS TECHNOLOGY CO., LTD., Wuhan (CN)

(72) Inventor: Jianlong HUANG, Wuhan (CN)

(73) Assignee: WUHAN CHINA STAR OPTOELECTRONICS TECHNOLOGY CO., LTD., Wuhan (CN)

(21) Appl. No.: 16/972,628

(22) PCT Filed: Nov. 4, 2020
(86) PCT No.: PCT/CN2020/126337

§ 371 Date: Dec. 7, 2020

(30) Foreign Application Priority Data
Sep. 23, 2020 (CN) 202011009756.4

(51) Int. Cl. G03F 1/32; G02F 1/1335; G02F 1/1333; G02F 1/1339

(52) U.S. Cl. CPC G03F 1/32; G02F 1/133512; G02F 1/133516; G02F 1/133357; G02F 1/1339

(57) ABSTRACT

A halftone mask, a manufacturing method of a display panel, and an ultraviolet mask are disclosed. The halftone mask includes a substrate, a plurality of light-blocking parts, and a plurality of semi-transmissive parts. Wherein, the semi-transmissive parts correspond to a thinned patterning area of a first target object and a hollowed patterning area of a second target object.

### FIELD OF INVENTION

The present disclosure relates to the field of display panel technologies, and more particularly, to a halftone mask, a manufacturing method of a display panel, and an ultraviolet mask.

### BACKGROUND OF INVENTION

Display devices, such as liquid crystal displays (LCDs), are widely used flat display devices. A manufacturing method thereof mainly includes providing two substrates in parallel to each other, coating a sealant between the two substrates, and instilling liquid crystals into a space formed by the sealant and the two substrates. Thin film transistors (TFTs) are disposed on the lower substrate, and a color filter (CF) is disposed on the upper substrate. A rotating direction of liquid crystal molecules in a liquid crystal cell is controlled by signals and voltage changes of the TFTs, so polarized light of each pixel to emit or not can be controlled, thereby realizing a display objective. At present, there are generally two ways for the industries to cure the sealant, that is, thermal curing and ultraviolet light (UV) curing.

At present, the ultraviolet light curing is mainly used in the industries. Because the sealant can be in contact with the liquid crystals before the sealant glue is cured, the UV curing is generally used in the industries to prevent the liquid crystals from being polluted caused by direct contact of the liquid crystals and the sealant. As shown in FIG. 1, the UV curing mainly uses an ultraviolet mask 100 to shield a liquid crystal area 200 (also called a display area, that is, an A/A area) of a display panel and to expose an area coated with a sealant 300 around a chip area 400 of the display panel, thereby UV curing the sealant 300 by an UV curing equipment. There are mainly two objectives to use the ultraviolet mask. First, it can prevent that high energy UV light directly irradiates on the liquid crystals to cause structures of the liquid crystals to be damaged and abnormal display. Second, it can prevent damages caused by direct irradiation of the UV light on TFT devices (especially channel doped parts). Manufacturing of the ultraviolet mask is generally performed on an opaque metal (a gate metal or a data metal in general) on a substrate in an order of photoresist deposition, masking, etching, and photoresist stripping.

In general, when manufacturing the LCDs, in addition to masks of TFT (array) substrates and color filter (CF) substrates, a special mask is required for manufacturing the ultraviolet mask. Some companies omit the ultraviolet mask, but manufactured panels have problems of abnormal display caused by damages of the liquid crystals or the TFT devices in a long-time use.

Technical problem: an embodiment of the present disclosure provides a halftone mask, a manufacturing method of a display panel, and an ultraviolet mask to reduce a number of masks and production cost of display panels.

### SUMMARY OF INVENTION

In a first aspect, the present disclosure provides a halftone mask which is configured to manufacture patterns of at least two target objects. The halftone mask includes:
a substrate;
a plurality of light-blocking parts formed on the substrate and blocking radiant light having a predetermined waveband;
a plurality of semi-transmissive parts formed on the substrate and transmitting a part of the radiant light, wherein, the semi-transmissive parts correspond to a thinned patterning area of a first target object and a hollowed patterning area of a second target object; and
a fully transmissive part formed on the substrate and fully transmitting the radiant light, wherein, the fully transmissive part corresponds to a hollowed patterning area of the first target object and another hollowed patterning area of the second target object, and the fully transmissive part surrounds the semi-transmissive parts.

In some embodiments, the first target object is an ultraviolet mask, and the second target object is a planarization layer of a display panel.

In a second aspect, the present disclosure provides a method for manufacturing the display panel. The method includes:
using the halftone mask in the first aspect to manufacture the patterns of the at least two target objects by adjusting an amount of exposure.

In some embodiments, using the halftone mask to manufacture the patterns of the at least two target objects by adjusting the amount of exposure includes:
forming a first photoresist on the first target object; and
exposing and etching the first target object formed with the first photoresist to form a thinned pattern corresponding to the semi-transmissive parts and a hollowed pattern corresponding to the fully transmissive part on the first target object by the semi-transmissive parts and the fully transmissive part of the halftone mask.

In some embodiments, using the halftone mask to manufacture the patterns of the at least two target objects by adjusting the amount of exposure further includes a following step:
disposing a protective layer on the first target object.

In some embodiments, the first target object is the ultraviolet mask, and the method of manufacturing the display panel further includes:
using the ultraviolet mask in a curing process to cure a sealant of the display panel by irradiating ultraviolet light through the hollowed pattern of the ultraviolet mask.

In some embodiments, using the halftone mask to manufacture the patterns of the at least two target objects by adjusting the amount of exposure includes:
forming a second photoresist on the second target object; and
exposing and etching the second target object formed with the second photoresist to form a hollowed pattern corresponding to the semi-transmissive parts and the fully transmissive part on the second target object by the semi-transmissive parts and the fully transmissive part of the halftone mask, wherein, the amount of exposure allows an exposed part of the second photoresist corresponding to the semi-transmissive parts to be completely etched.

In some embodiments, the second target object is a planarization layer.

In a third aspect, the present disclosure provides the ultraviolet mask including:
the hollowed pattern; and
the thinned pattern corresponding to the semi-transmissive parts of the halftone mask.

In some embodiments, the hollowed pattern is arranged surrounding the thinned pattern of the ultraviolet mask.

Beneficial effect: by having the semi-transmissive parts of the halftone mask to respectively correspond to the thinned patterning area of the first target object and the hollowed patterning area of the second target object, the halftone mask provided in the present disclosure can act as a mask for multiple target objects in a manufacturing process of liquid crystal display panels, thereby achieving objectives of saving masks and production cost. The present disclosure also provides the method for manufacturing the display panel using the halftone mask. The manufacturing process can be simplified and the production cost of the display panel can be reduced by adjusting the amount of exposure to form patterns of one or more target objects.

### DESCRIPTION OF DRAWINGS

The accompanying figures to be used in the description of embodiments of the present disclosure will be described in brief to illustrate the technical solutions of the embodiments more clearly. The accompanying figures described below are only part of the embodiments of the present disclosure, from which those skilled in the art can derive further figures without making any inventive efforts.

FIG. 1 is a schematic structural diagram of an ultraviolet mask in current technology.

FIG. 2 is a schematic structural diagram of a halftone mask according to an embodiment of the present disclosure.

FIG. 3 is a schematic processing diagram of a first target object according to an embodiment of the present disclosure.

FIG. 4 is a schematic processing diagram of a second target object according to an embodiment of the present disclosure.

FIG. 5 is a schematic structural diagram of an ultraviolet mask according to an embodiment of the present disclosure.

### DETAILED DESCRIPTION OF PREFERRED EMBODIMENTS

The technical solutions in the embodiments of the present disclosure will be clearly and completely described below with reference to the drawings in the embodiments of the present disclosure. Obviously, the described embodiments are only a part of the embodiments of the present disclosure, but not all the embodiments. Based on the embodiments in the present disclosure, all other embodiments obtained by those skilled in the art without creative efforts are within the scope of the present disclosure.

In the description of the present disclosure, it should be understood that terms such as “center”, “longitudinal”, “lateral”, “length”, “width”, “thickness”, “upper”, “lower”, “front”, “rear”, “left”, “right”, “vertical”, “horizontal”, “top”, “bottom”, “inside”, “outside”, as well as derivative thereof should be construed to refer to the orientation as described or as shown in the drawings under discussion. These relative terms are for convenience of description, do not require that the present disclosure be constructed or operated in a particular orientation, and shall not be construed as causing limitations to the present disclosure. In addition, terms such as “first” and “second” are used herein for purposes of description and are not intended to indicate or imply relative importance or implicitly indicating the number of technical features indicated. Thus, features limited by “first” and “second” are intended to indicate or imply including one or more than one these features. In the description of the present disclosure, “a plurality of” relates to two or more than two, unless otherwise specified.

When manufacturing liquid crystal display panels, saving masks, thereby saving production cost of the liquid crystal display panels, has always been what technicians are striving for.

Based on this, an embodiment of the present disclosure provides a halftone mask, a manufacturing method of a display panel, and an ultraviolet mask. They are described in detail in the following.

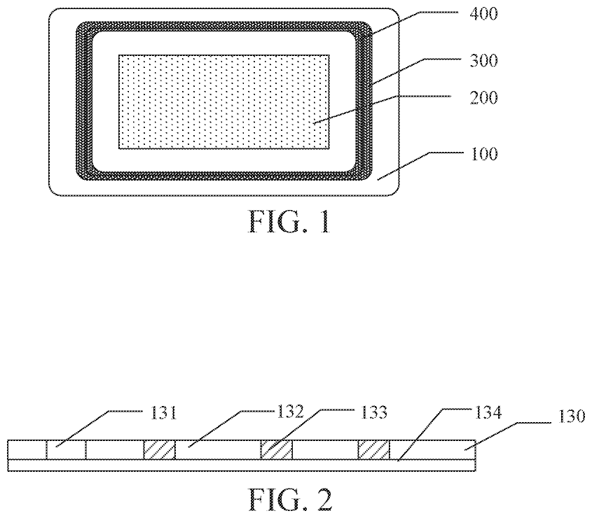

First, referring to FIG. 2, an embodiment of the present disclosure provides the halftone mask 130, which may be used to manufacture patterns of at least two target objects. The halftone mask includes a substrate 134, a plurality of light-blocking parts 132, and a plurality of semi-transmissive parts 133.

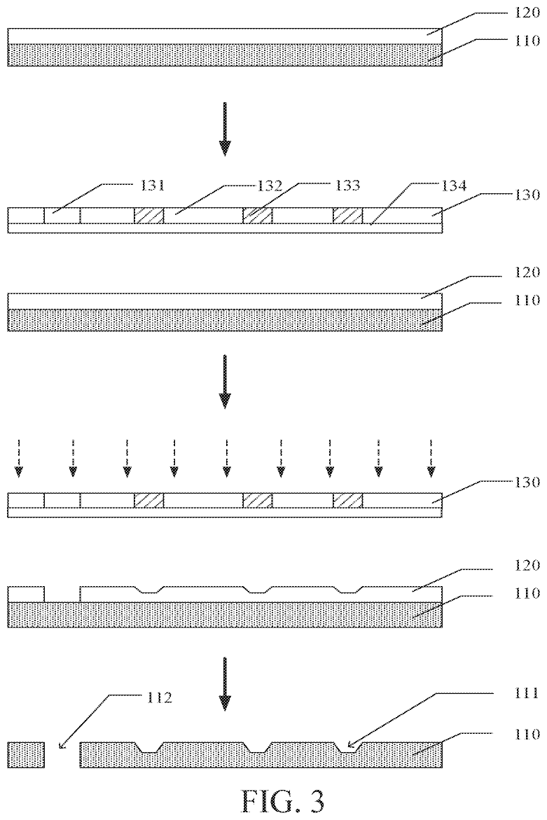

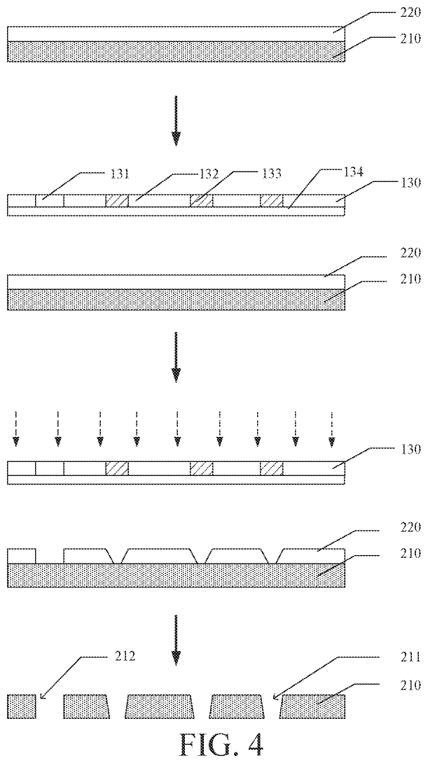

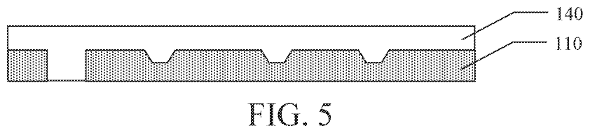

The light-blocking parts 132 and the semi-transmissive parts 133 are both positioned on the substrate 134. The light-blocking parts 132 are used to block radiant light having a predetermined waveband, and the semi-transmissive parts 133 may transmit a part of the radiant light having the predetermined waveband.

Wherein, when there are multiple target objects, for example, two, as shown in FIGS. 3 and 4, the semi-transmissive parts 133 correspond to a thinned patterning area 111 of a first target object 110 and a hollowed patterning area 211 of a second target object 210, thereby allowing the halftone mask 130 to simultaneously correspond to patterns of the multiple target objects for manufacturing.

The halftone mask 130 provided in this embodiment has the semi-transmissive parts 133 to correspond to the thinned patterning area 111 of the first target object 110 and the hollowed patterning area 211 of the second target object 210. Wherein, although the thinned patterning area 111 loses a part of film layer thickness, it is still in a non-hollowed state and has a certain degree of opaqueness, so light-shielding ability is not affected. Therefore, the halftone mask 130 can act as a mask for multiple types of target objects in a manufacturing process of liquid crystal display panels, thereby achieving objectives of saving masks and production cost.

Based on the above embodiment, in another specific embodiment of the present disclosure, the halftone mask 130 further includes a fully transmissive part 131 formed on the substrate 134 and fully transmitting the radiant light. The fully transmissive part 131 corresponds to a hollowed patterning area 112 of the first target object 110 and another hollowed patterning area 212 of the second target object 210. In an embodiment, the fully transmissive part 131 surrounds the semi-transmissive parts 133. Wherein, the fully transmissive part 131 may correspond to a position of a sealant of the display panel, and the semi-transmissive parts 133 may correspond to opening holes in a display area and/or in a sealant area around a chip area in a planarization layer.

For example, the first target object 110 is the ultraviolet mask, and the second target object 210 is the planarization layer, and the halftone mask 130 can be used in a manufacturing process of the ultraviolet mask and the planarization layer.

At present, in addition to the opening holes in the display area and the sealant area around the chip area requiring to be trenched, other parts of a pattern of the planarization layer of the display panel are basically consistent with a pattern of the ultraviolet mask. Designing an extra mask for curing the sealant will greatly increase the production cost. This embodiment can allow the ultraviolet mask and the planarization layer to share a same mask by using the halftone mask 130. The semi-transmissive parts 133 of the halftone mask 130 can be used to respectively manufacture a thinned patterning area 111 of the ultraviolet mask and a hollowed patterning area 211 of the planarization layer, and the fully transmissive part 131 of the halftone mask 130 can be used to manufacture a hollowed patterning area 112 of the ultraviolet mask and another hollowed patterning area 212 of the planarization layer. Therefore, a number of the masks can be saved, and the production cost can be reduced.

Refer to FIGS. 3 and 4. Based on the above embodiments, an embodiment of the present disclosure further provides a method for manufacturing the display panel. The method includes:
using the halftone mask 130 described in any one of the above embodiments to manufacture the patterns of the at least two target objects by adjusting an amount of exposure.

Specifically, when the amount of exposure is lower, the halftone mask 130 is used to manufacture a thinned patterning area 111 of one target object, and when the amount of exposure is higher, the halftone mask 130 is used to manufacture a hollowed patterning area 211 of another target object.

This embodiment manufacturing patterns of one or more target objects by adjusting the amount of exposure of the halftone mask 130 makes a part of the manufacturing process of the display panel simplified, thereby reducing the production cost of the display panel.

As shown in FIG. 3, based on the above embodiments, in another embodiment of the present disclosure, a manufacturing method of the first target object 110 is specifically as follows.

S11: Forming a first photoresist 120 on the first target object 110.

S21: Providing the halftone mask 130.

S31: Exposing the first target object 110 formed with the first photoresist 120 by the semi-transmissive parts 133 and the fully transmissive part 131 of the halftone mask 130.

S41: etching the first target object 110 after exposure to form a thinned pattern 111 corresponding to the semi-transmissive parts 133 and a hollowed pattern 211 corresponding to the fully transmissive part 131 on the first target object 110.

In an embodiment of the present disclosure, the first target object 110 is the ultraviolet mask.

As shown in FIG. 4, a manufacturing method of the second target object 210 is specifically as follows.

S21: Forming a second photoresist 220 on the second target object 210.

S22: Providing the halftone mask 130.

S32: Exposing the second target object 210 formed with the second photoresist 220 by the semi-transmissive parts 133 and the fully transmissive part 131 of the halftone mask 130.

S42: etching the second target object 210 after exposure to form a hollowed pattern corresponding to the semi-transmissive parts 133 and the fully transmissive part 131 on the second target object 210. Wherein, the amount of exposure allows an exposed part of the second photoresist 220 corresponding to the semi-transmissive parts 133 to be completely etched.

Specifically, in the above embodiments, the first target object 110 and the second target object 210 use the same halftone mask 130.

In an embodiment of the present disclosure, the second target object 210 is the planarization layer.

In an embodiment of the present disclosure, steps of the exposure and etching specifically include:
exposing the first photoresist 120 or the second photoresist 220 by the halftone mask 130;
developing the first photoresist 120 or the second photoresist 220 after exposure; and
etching the first target object 110 or the second target object 210.

Wherein, the etching may be dry etching or wet etching.

In an embodiment, the method further includes a step of disposing a protective layer 140 on the first target object 210. The protective layer 140 is used to prevent the first target object 210 from being oxidized or worn.

Wherein, the fully transmissive part 131 of the halftone mask 130 may correspond to the hollowed patterning area 112 of the ultraviolet mask and the another hollowed patterning area 212 of the planarization layer. As shown in FIGS. 2 and 3, the hollowed patterning area 112 of the ultraviolet mask and the another hollowed patterning area 212 of the planarization layer may be used as openings for the sealant in the ultraviolet mask and the planarization layer.

When the halftone mask 130 in the embodiment of the present disclosure is used to manufacture the ultraviolet mask, a position on the ultraviolet mask corresponding to the fully transmissive part 131 can be completely etched to obtain the hollowed pattern 112, and a position on the ultraviolet mask corresponding to the semi-transmissive parts 133 will be partially etched to obtain the thinned pattern 111. Although the thinned pattern 111 loses a part of film layer thickness, it is still in an opaque state, so light-shielding ability is not affected. Therefore, when the ultraviolet mask is used to cure the sealant, only the hollowed pattern 112 of the ultraviolet mask can allow ultraviolet light to pass, so the sealant of the display panel can be cured, and other areas of the display panel will not be irradiated.

When the halftone mask 130 in the embodiment of the present disclosure is used to manufacture the planarization layer of the display panel, a position on the planarization layer corresponding to the semi-transmissive parts 133 can still receive adequate amount of exposure by increasing the amount of exposure, and after developing and etching, grooves of the planarization layer can be completely opened, thereby achieving an effect of using an independent mask before. Therefore, without changing TFT display principles, the planarization layer and the ultraviolet mask can be manufactured by the same mask, thereby saving one mask and reducing the production cost.

It should be noted that only pattern manufacturing processes of the ultraviolet mask and the planarization layer are described in the above embodiments of the manufacturing method of the display panel. However, it can be understood that in addition to the above processes, in the display panel of the embodiments of the present disclosure, other processes are also included, and they will not be described herein.

Referring to FIG. 5, the present disclosure further provides the ultraviolet mask manufactured by the halftone mask 130 described in any one of the above embodiments. The ultraviolet mask includes the hollowed pattern 112 and the thinned pattern 111 corresponding to the semi-transmissive parts 133 of the halftone mask 130.

Wherein, the hollowed pattern 112 is arranged surrounding the thinned pattern 111 of the ultraviolet mask.

The present disclosure further provides the display panel, which uses the ultraviolet mask of the above embodiments to cure the sealant of the display panel or is manufactured by the manufacturing method of the display panel described in any one of the above embodiments.

In the above embodiments, the description of each embodiment has its own emphasis. For the parts that are not described in detail in an embodiment, refer to the detailed description of other embodiments above, which will not be repeated here.

In specific implementation, each of the above units or structures can be implemented as independent entities, or can be combined arbitrarily to be implemented as the same or several entities. The specific implementation of each of the above units or structures can be referred to the previous method embodiments, and will not be repeated here.

The specific implementation of the above operations can be referred to the previous embodiments, and will not be repeated here.

The halftone mask, the manufacturing method of the display panel, and the ultraviolet mask provided by the embodiments of the present disclosure are described in detail above. Specific examples are used herein to explain the principles and implementation of the present disclosure. The descriptions of the above embodiments are only used to help understand the method of the present disclosure and its core ideas; meanwhile, for those skilled in the art, the range of specific implementation and application may be changed according to the ideas of the present disclosure. In summary, the content of the specification should not be construed as causing limitations to the present disclosure.

What is claimed is:

1. A halftone mask configured to manufacture patterns of at least two target objects, comprising:
a substrate;
a plurality of light-blocking parts formed on the substrate and blocking radiant light having a predetermined waveband;
a plurality of semi-transmissive parts formed on the substrate and transmitting a part of the radiant light, wherein the semi-transmissive parts correspond to a thinned patterning area of a first target object and a hollowed patterning area of a second target object; and
a fully transmissive part formed on the substrate and fully transmitting the radiant light, wherein the fully transmissive part corresponds to a hollowed patterning area of the first target object and another hollowed patterning area of the second target object, and the fully transmissive part surrounds the semi-transmissive parts.

2. The halftone mask according to claim 1, wherein the first target object is an ultraviolet mask, and the second target object is a planarization layer of a display panel.

3. A method for manufacturing a display panel, comprising:
using the halftone mask according to claim 1 to manufacture the patterns of the at least two target objects by adjusting an amount of exposure.

4. The method for manufacturing the display panel according to claim 3, wherein using the halftone mask to manufacture the patterns of the at least two target objects by adjusting the amount of exposure comprises:
forming a first photoresist on the first target object; and
exposing and etching the first target object formed with the first photoresist to form a thinned pattern corresponding to the semi-transmissive parts and a hollowed pattern corresponding to the fully transmissive part on the first target object by the semi-transmissive parts and the fully transmissive part of the halftone mask.

5. The method for manufacturing the display panel according to claim 4, wherein using the halftone mask to manufacture the patterns of the at least two target objects by adjusting the amount of exposure further comprises a following step:
disposing a protective layer on the first target object.

6. The method for manufacturing the display panel according to claim 5, wherein the first target object is an ultraviolet mask, and the method further comprises:
using the ultraviolet mask in a curing process to cure a sealant of the display panel by irradiating ultraviolet light through the hollowed pattern of the ultraviolet mask.

7. The method for manufacturing the display panel according to claim 4, wherein using the halftone mask to manufacture the patterns of the at least two target objects by adjusting the amount of exposure comprises:
forming a second photoresist on the second target object; and
exposing and etching the second target object formed with the second photoresist to form a hollowed pattern corresponding to the semi-transmissive parts and the fully transmissive part on the second target object by the semi-transmissive parts and the fully transmissive part of the halftone mask, wherein the amount of exposure allows an exposed part of the second photoresist corresponding to the semi-transmissive parts to be completely etched.

8. The method for manufacturing the display panel according to claim 7, wherein the second target object is a planarization layer.

9. The method for manufacturing the display panel according to claim 6, wherein using the halftone mask to manufacture the patterns of the at least two target objects by adjusting the amount of exposure comprises:
forming a second photoresist on the second target object; and
exposing and etching the second target object formed with the second photoresist to form a hollowed pattern corresponding to the semi-transmissive parts and the fully transmissive part on the second target object by the semi-transmissive parts and the fully transmissive part of the halftone mask, wherein the amount of exposure allows an exposed part of the second photoresist corresponding to the semi-transmissive parts to be completely etched.

10. The method for manufacturing the display panel according to claim 9, wherein the second target object is a planarization layer.

11. An ultraviolet mask manufactured by the halftone mask according to claim 1, comprising:
a hollowed pattern; and
a thinned pattern corresponding to the semi-transmissive parts of the halftone mask.

12. The ultraviolet mask according to claim 11, wherein the hollowed pattern is arranged surrounding the thinned pattern of the ultraviolet mask.
